(19) United States
(12) Patent Application Publication
(10) Pub. No.: US 2025/0169023 A1
(43) Pub. Date: May 22, 2025

(54) SYSTEMS AND METHODS FOR STRANDED-LESS POWER DATACENTERS

(71) Applicant: Microsoft Technology Licensing, LLC, Redmond, WA (US)

(72) Inventors: Ehsan NASR AZADANI, Sammamish, WA (US); Ruslan NAGIMOV, Redmond, WA (US); Christian L. BELADY, Mercer Island, WA (US)

(21) Appl. No.: 18/518,016

(22) Filed: Nov. 22, 2023

(51) Int. Cl. H05K 7/14

(52) U.S. Cl. CPC H05K 7/1492

(57) ABSTRACT

A system may include a grid connection configured to receive grid electrical power at a grid voltage, a grid amperage, and a grid frequency. A system may include a co-location including a plurality of computing devices. A system may include a solid-state transformer in electrical communication with the grid connection and configured to convert the grid electrical power to co-location electrical power having a co-location voltage different from the grid voltage and a co-location amperage different from the grid amperage. A system may include a superconducting cable providing electrical communication of the co-location electrical power from the solid-state transformer to the co-location.

### BACKGROUND

Datacenters require a robust electrical power system to meet the power demands of highly variable computational loads. Failures in a conventional datacenter power distribution systems can strand power, causing reduced utilization of electrical equipment and computational resources.

### BRIEF SUMMARY

In some aspects, the techniques described herein relate to a datacenter power system including: a grid connection configured to receive grid electrical power at a grid voltage, a grid amperage, and a grid frequency; a co-location including a plurality of computing devices; a solid-state transformer in electrical communication with the grid connection and configured to convert the grid electrical power to co-location electrical power having a co-location voltage different from the grid voltage and a co-location amperage different from the grid amperage; and a superconducting cable providing electrical communication of the co-location electrical power from the solid-state transformer to the co-location.

In some aspects, the techniques described herein relate to a method of power management in a datacenter, the method including: receiving grid electrical power at a grid connection, wherein the grid electrical power has a grid voltage, a grid amperage, and a grid frequency; converting the grid electrical power to co-location electrical power having a co-location voltage different from the grid voltage and a co-location amperage different from the grid amperage with a solid-state transformer; and communicating the co-location electrical power to a co-location of the datacenter with a superconducting cable.

In some aspects, the techniques described herein relate to a datacenter power system including: a grid connection configured to receive grid electrical power at a grid voltage, a grid amperage, and a grid frequency; a plurality of co-locations, each co-location including a plurality of computing devices; a solid-state transformer in electrical communication with the grid connection and configured to convert the grid electrical power to co-location electrical power having a co-location voltage different from the grid voltage and a co-location amperage different from the grid amperage; a superconducting cable providing electrical communication of the co-location electrical power from the solid-state transformer to the co-location; and a plurality of branch conduits from the superconducting cable that provide electrical communication to the plurality of co-locations.

This Summary is provided to introduce a selection of concepts in a simplified form that are further described below in the Detailed Description. This Summary is not intended to identify key features or essential features of the claimed subject matter. Additional features and advantages will be set forth in the description which follows, and in part will be obvious from the description, or may be learned by the practice of the teachings herein. Features and advantages of the disclosure may be realized and obtained by means of the instruments and combinations particularly pointed out in the appended claims. Features of the present disclosure will become more fully apparent from the following description and appended claims or may be learned by the practice of the disclosure as set forth hereinafter.

### BRIEF DESCRIPTION OF THE DRAWINGS

In order to describe the manner in which the above-recited and other features of the disclosure can be obtained, a more particular description will be rendered by reference to specific embodiments thereof which are illustrated in the appended drawings. For better understanding, the like elements have been designated by like reference numbers throughout the various accompanying figures. While some of the drawings may be schematic or exaggerated representations of concepts, at least some of the drawings may be drawn to scale. Understanding that the drawings depict some example embodiments, the embodiments will be described and explained with additional specificity and detail through the use of the accompanying drawings in which:

FIG. 1 is a schematic representation of a conventional datacenter power system.

FIG. 2 is a schematic representation of a datacenter power system including a solid-state transformer, according to at least some embodiments of the present disclosure.

FIG. 3 is a schematic representation of a datacenter power system including supplemental power sources, according to at least some embodiments of the present disclosure.

FIG. 4 is a schematic representation of a datacenter power system including staged conversion of electrical power, according to at least some embodiments of the present disclosure.

FIG. 5 is a schematic representation of a datacenter power system including supplemental power sources, according to at least some embodiments of the present disclosure.

FIG. 6 is a flowchart illustrating a method of datacenter power management, according to at least some embodiments of the present disclosure.

FIG. 7 is a schematic representation of a datacenter power system including grid participation, according to at least some embodiments of the present disclosure.

### DETAILED DESCRIPTION

The present disclosure generally relates to systems and methods for converting and providing electrical power to a datacenter. In some embodiments, a datacenter power system according to the present disclosure provides more efficient power conversion from a utility grid to a voltage usable for server computers and other computing devices in a datacenter. More particularly, a datacenter power system, in some embodiments, includes a solid-state transformer configured to convert high-voltage grid electrical power to a low-voltage co-location electrical power in a single device, improving efficiency in a lighter and/or smaller package,.

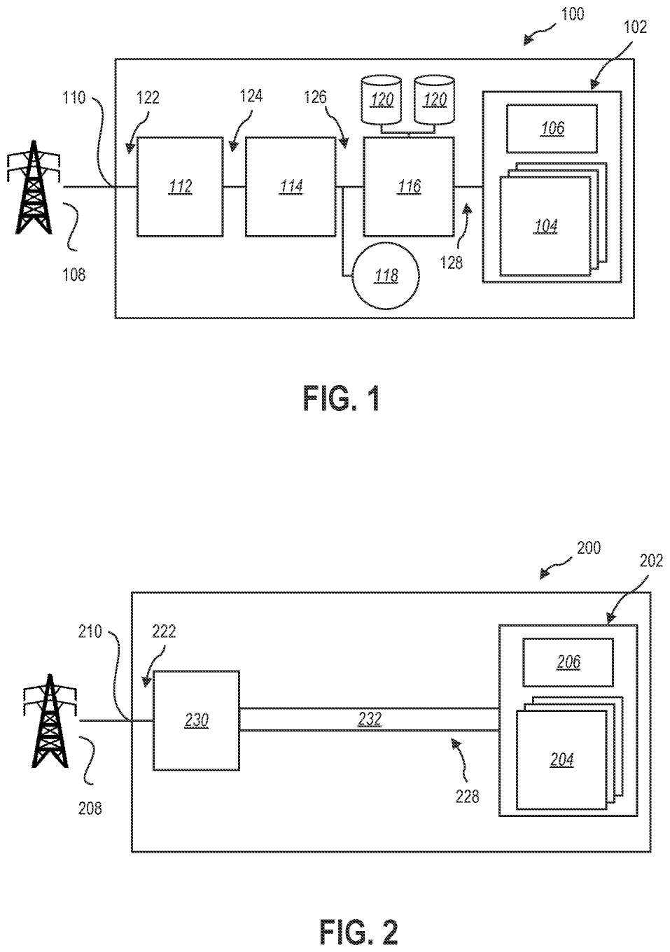

FIG. 1 is a system diagram of a conventional system for providing and managing electrical power in a datacenter. The datacenter power system 100 provides electrical power to, among other portions of the datacenter, one or more co-locations 102. The co-locations 102 include a plurality of computing devices 104. In some examples, the co-location 102 includes a power supply unit (PSU) 106 that receives, converts, and distributes electrical power to the computing devices 104.

The datacenter power system 100, in some examples, receives grid electrical power from a regional utility grid 108. The regional utility grid 108 provides the grid electrical power at a higher voltage than the co-location 102 can utilize, and the datacenter power system 100 converts the grid electrical power for use in the co-locations 102 of the datacenter. For example, the datacenter power system 100 receives the grid electrical power through a grid connection 110 to a high voltage transformer 112 that steps the voltage down. In some examples, the datacenter power system 100 then includes a middle voltage transformer 114 and a low voltage transformer 114 to further step the voltage down in stages and the amperage of the electrical current increases with each step down of voltage. The electrical conduits and the datacenter power system 100, as a whole, must compensate for the increased amperage.

For example, as the amperage through a resistive electrical conduit (e.g., copper wire or cable) increases, the resistivity of the resistive electrical conduit converts a portion of the electrical power to heat and other loss mechanisms. The electrical loss and heat generation are undesirable in the datacenter power system 100. Therefore, conventional systems step the voltage down in stages. In some examples, the datacenter power system 100 may include additional power sources or storage devices, such as a generator 118 and/or battery storage devices 120. In some examples, the additional power sources or storage devices, such as the generator 118 and/or battery storage devices 120, are coupled to the datacenter power system 100 at different stages of the voltage depending on the provided voltage of the additional power sources or storage devices.

In the illustrated example of FIG. 1, the datacenter power system 100 receives a high voltage grid electrical power 122 through the grid connection 110 to the high voltage transformer 112. The incoming grid electrical power 122 is received with a grid voltage, a grid amperage, and a grid frequency. In some examples, the grid voltage is a high voltage no less than 110 kilovolts (kV). In some examples, the grid voltage is an extra-high voltage no less than 345 kV. In some examples, the grid voltage is an ultra-high voltage no less than 1100 kV. Stepping down the grid voltage can produce high amperage, as the voltage and amperage are inversely proportional for a given power (Wattage), assuming limited or no losses during conversion.

For example, stepping down the grid voltage of the grid electrical power 122 through the high voltage transformer 112 to a middle voltage electrical power 124 having a middle voltage ten times less than the grid voltage results in a middle amperage ten times greater than the grid amperage. Further step-downs of the middle voltage electrical power 124 to a low voltage electrical power 126 through the middle voltage transformer 114, and of the low voltage electrical power 126 to a co-location electrical power 128 usable by the co-location 102 through the low voltage transformer 116 can continue increasing the amperage by orders of magnitude. As datacenters commonly consume electrical power on the order of Megawatts, the amperage needs to be managed at each step-down in a conventional datacenter power system 100 to avoid excessive electrical losses and heat generation.

FIG. 2 is a schematic diagram of a datacenter power system 200 according to at least some embodiments of the present disclosure. At least a portion of the series of conventional transformers (112, 114, 116) described in relation to FIG. 1 are replaced with a solid-state transformer 230. In some embodiments, the solid-state transformer converts the high grid voltage of the grid electrical power 222 to a co-location voltage of a co-location electrical power 228 usable by a co-location 202 in a single step-down through multi-stage power electronic conversion.

The datacenter power system 200 provides the co-location electrical power 228 to the co-location 202. In some embodiments, the co-location 202 includes a PSU that receives and distributes the co-location electrical power 228 to the computing devices 204 of the co-location 202. In some embodiments, the co-location 202 does not have a PSU 206, and the co-location electrical power 228 is delivered to the plurality of computing devices 204 directly and/or without any changes to the co-location voltage, co-location amperage, co-location frequency, or combinations thereof.

In some embodiments, the co-location 202 includes a plurality of computing devices 204 in one or more server racks. In some embodiments, the co-location 202 includes a plurality of computing devices 204 in one or more server rows containing a plurality of server racks. In some embodiments, the co-location 202 includes a plurality of computing devices 204 in one or more server rooms containing a plurality of server rows. In some embodiments, the datacenter power system 200 distributes the co-location electrical power 228 to a plurality of co-locations 202.

In some embodiments, the solid-state transformer 230 is an alternating current (AC)-to-AC transformer. In some embodiments, the solid-state transformer 230 can actively regulate voltage and amperage, allowing the solid-state transformer 230 to step-down the grid voltage and also convert a grid frequency of the grid electrical power 222. In some examples, the solid-state transformer can convert single-phase AC power to three-phase AC power and/or convert three-phase AC power to single-phase AC power. In some embodiments, the solid-state transformer 230 receives an AC input power and outputs a direct current (DC) output power.

The datacenter power system 200 receives high voltage grid electrical power 222 from the utility grid 208 through a grid connection 210. The incoming grid electrical power 222 is received with a grid voltage, a grid amperage, and a grid frequency. In some embodiments, the grid voltage is a high voltage no less than 110 kV. In some embodiments, the grid voltage is an extra-high voltage no less than 345 kV. In some embodiments, the grid voltage is an ultra-high voltage no less than 1100 kV. Stepping down the grid voltage to the co-location voltage of the co-location electrical power 228 produces a high amperage, as the voltage and amperage are inversely proportional for a given power (Watts), assuming limited or no losses during conversion. With less transformers in the power train, a solid-state transformer 230 allows some embodiments of a datacenter power system 200 to be more efficient, more flexible, and with smaller and lighter power electronic systems.

In some embodiments, the co-location electrical power 228 has a co-location voltage that is no more than 240 Volts (V). In some embodiments, the co-location electrical power 228 has a co-location voltage that is no more than 120 V. In some embodiments, the co-location electrical power 228 has a co-location voltage that is no more than 48 V. In some embodiments, the co-location electrical power 228 has a co-location voltage that is no more than 12 V. In some embodiments, the co-location electrical power 228 has a co-location voltage that is no more than 5 V.

The greater the step-down in voltage across the solid-state transformer 230, the greater the increase in amperage. In some embodiments, the co-location amperage is greater than 900 times the grid amperage. To communicate the co-location electrical power 228 to the co-location(s) 202, in some embodiments, a datacenter power system 200 includes a superconducting cable 232. A superconducting cable is a wire, cable, or other electrical conduit that conducts electricity with substantially zero resistance across the length of the electrical conduit when below a critical temperature. In some embodiments, the superconducting cable 232 includes a high-temperature superconductor (HTS) with a critical temperature no less than 30 Kelvin (K). In some embodiments, the superconducting cable 232 includes an HTS with a critical temperature no less than 77 K. In some embodiments, the superconducting cable 232 includes a low-temperature superconductor with a critical temperature less than 30 K. In some embodiments, the superconducting cable 232 is cooled and/or maintained below the critical temperature using low-temperature refrigerants, such as liquid nitrogen, liquid helium, or other liquid or gas coolants, solid-state cooling, or combinations thereof.

In at least some embodiments, the superconducting cable 232 provides electrical communication of the co-location electrical power 228 from the solid-state transformer 230 to the co-location 202 directly with no intervening electrical components. In some embodiments, the superconducting cable 232 provides electrical communication for at least a portion of the electrical connection between the solid-state transformer 230 to the co-location 202. For example, and as will be described in more detail herein, the superconducting cable 232 may provide electrical communication to a second transformer or other electrical component between the solid-state transformer 230 and the co-location 202.

In some embodiments, at least a portion of the superconducting cable 232 communicates electrical power (e.g., co-location electrical power 228) having an amperage (e.g., co-location amperage) greater than 90,000 A. In some embodiments, the entire superconducting cable 232 communicates electrical power having an amperage greater than 90,000 A. For example, a grid electrical power 222 with a 110 kV grid voltage and 100 A grid amperage may be converted to a co-location electrical power 228 with a 120 V co-location voltage and an approximate 91,700 A co-location amperage. In some embodiments, at least a portion of the superconducting cable 232 communicates electrical power (e.g., co-location electrical power 228) having an amperage (e.g., co-location amperage) greater than 200,000 A. For example, a grid electrical power 222 with a 110 kV grid voltage and 100 A grid amperage may be converted to a co-location electrical power 228 with a 48 V co-location voltage and an approximate 229,000 A co-location amperage. In some embodiments, at least a portion of the superconducting cable 232 communicates electrical power (e.g., co-location electrical power 228) having an amperage (e.g., co-location amperage) greater than 2,000,000 A. For example, a grid electrical power 222 with a 110 kV grid voltage and 100 A grid amperage may be converted to a co-location electrical power 228 with a 48 V co-location voltage and an approximate 2,200,000 A co-location amperage. In some embodiments, co-location amperage could be split into multiple parallel superconducting cables each carrying a fraction of the total amperage.

A superconducting cable 232 conveys the electrical power with substantially no resistance, allowing high amperages without the associated electrical loss and heat generation of resistive conduits, such as copper wire or cable. In some embodiments, the superconducting cable 232 includes or is made of a first-generation or second-generation superconductors. First-generation superconductors include, in some examples, bismuth strontium calcium copper oxide materials. In some examples, second-generation superconductors include rare-earth barium copper oxide materials.

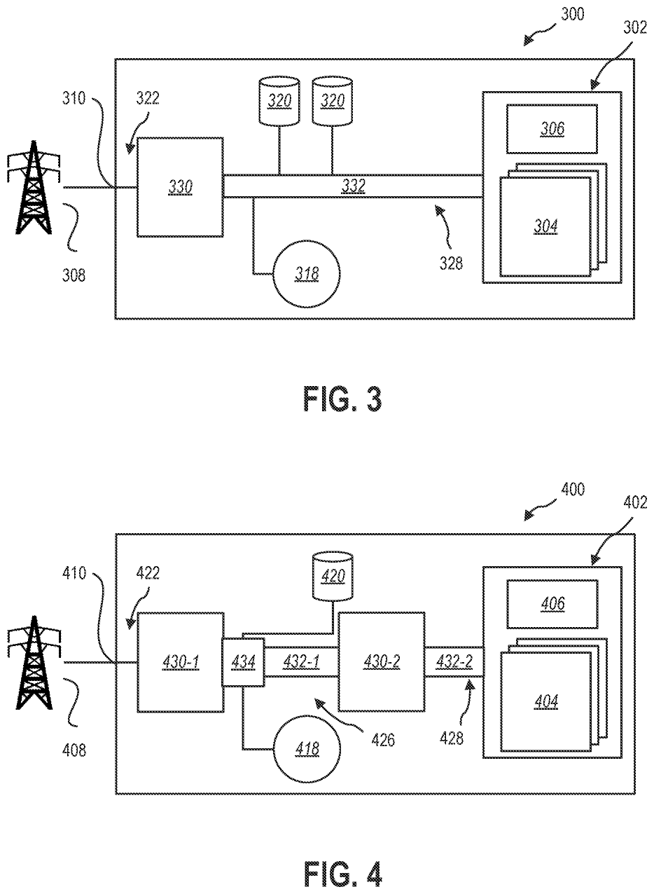

FIG. 3 is a schematic representation of a datacenter power system 300 including supplemental power sources and/or power supplies, according to at least some embodiments of the present disclosure. In some embodiments, the datacenter power system 300 includes additional power sources or storage devices, such as a generator 318 and/or battery storage devices 320 electrically between the solid-state transformer 330 and the co-location 302 (e.g., at the superconducting cable 332). In at least one example, the generator 318 and/or battery storage devices 320 is coupled through an AC or DC link of the solid-state transformer. In some examples, the additional power sources or storage devices, such as the generator 318 and/or battery storage devices 320, are coupled to the datacenter power system 300 at different stages of the voltage depending on the provided voltage of the additional power sources or storage devices.

In some embodiments, the grid 308 provides different amounts of grid electrical power 322 to the grid connection 310 depending on time of day, day of the week, time of the year, weather, local grid infrastructure, etc. In some embodiments, a datacenter power system 300 includes additional power sources or storage devices to supplement the electrical power in the datacenter, such as the available co-location electrical power 328. In some embodiments, a generator 318 (e.g., solar generator, thermal generator, combustion generator, fuel-cell generator) provides additional electrical power to the co-location electrical power 328 to supplement the co-location electrical power when the grid electrical power 322 is less than required by the co-locations 302 of the datacenter. In some embodiments, a storage device 320 (such as a battery) can receive and store surplus electrical power when available. In some embodiments, a storage device 320 (such as a battery, hydrogen fuel cell, metal fuel cell) can provide additional electrical power to the co-location electrical power 328 when the grid electrical power 322 is less than required by the co-locations 302 of the datacenter.

In some embodiments, the additional power sources or storage devices provide the additional electrical power to the co-location electrical power 328 at the co-location voltage and co-location frequency for use at the co-location 302 (either directly by the computing devices 304 or via a PSU 306). In some embodiments, the power sources or storage devices provide additional electrical power at different voltage and frequency (including direct current) than the co-location electrical power 328. In such embodiments, the additional power sources or storage devices may provide the additional electrical power to the power train between a solid-state transformers.

FIG. 4 is a schematic representation of a datacenter power system 400 including staged conversion of electrical power, according to at least some embodiments of the present disclosure. In such embodiments, additional power sources or storage devices provide additional electrical power at the middle-voltage electrical power or low-voltage electrical power 426. For example, the generator 418 and/or energy storage device(s) 420 may provide power to an uninterruptable power supply (UPS) electrically between a first solid-state transformer 430-1 and a second solid-state transformer 430-2. A component, device, conduit, or location of the datacenter power system 400 is electrically between a first component and a second component when the electrical power passes through that component, device, conduit, or location during transmission from the first component to the second component. For example, the first superconducting cable 432-1 may be electrically between the first solid-state transformer 430-1 and the second solid-state transformer 430-2, and the second superconducting cable 432-2 may be electrically between the second solid-state transformer 430-2 and the co-location 402.

In some embodiments, the first solid-state transformer 430-1 converts the grid electrical power 422 received from the grid 408 at the grid connection 410 to a lower voltage and higher amperage electrical power, such as the low-voltage electrical power 426 of FIG. 4. In some embodiments, additional power sources and/or storage devices provide additional power at the low voltage of the low-voltage electrical power 426 to supplement the available power that is provided to the second solid-state transformer 430-2. The second solid-state transformer 430-2 subsequently steps the voltage of the low-voltage electrical power 426 down to the co-location voltage of the co-location electrical power 428 in the second superconducting cable 432-2.

In some embodiments, the plurality of computing devices 404 of the co-location 402 can utilize the co-location electrical power 428 at the co-location voltage. In some embodiments, the co-location 402 includes a PSU 406 that receives and distributes the co-location electrical power 428 to the computing devices 404 of the co-location 402. In some embodiments, the co-location 402 does not have a PSU 406, and the co-location electrical power 428 is delivered to the plurality of computing devices 404 directly and/or without any changes to the co-location voltage, co-location amperage, co-location frequency, or combinations thereof.

In some embodiments, a DC UPS 434 is electrically between the first solid-state transformer 430-1 and the first superconducting cable 432-1 (and/or between the second solid-state transformer 430-2 and the second superconducting cable 432-2). The DC UPS 434 receives electrical power from the first solid-state transformer 430-1 and discharges to the first superconducting cable 432-1 to provide an uninterrupted electrical power in the event of a change to or loss of the grid electrical power 422.

In some embodiments, a generator 418 provides additional electrical power electrically between the first solid-state transformer 430-1 and the first superconducting cable 432-1 (and/or between the second solid-state transformer 430-2 and the second superconducting cable 432-2). In some embodiments, the generator 418 provides the additional electrical power at the output voltage and frequency of the adjacent solid-state transformer 430-1 in the event of a change to or loss of the grid electrical power 422.

In some embodiments, a generator UPS (gUPS) (418, 434) is between the first solid-state transformer 430-1 and the first superconducting cable 432-1 (and/or between the second solid-state transformer 430-2 and the second superconducting cable 432-2). In some embodiments, the gUPS 418, 434 allows a generator to provide an uninterrupted electrical power in the event of a change to or loss of the grid electrical power 422 at the output voltage and frequency of the adjacent solid-state transformer 430-1.

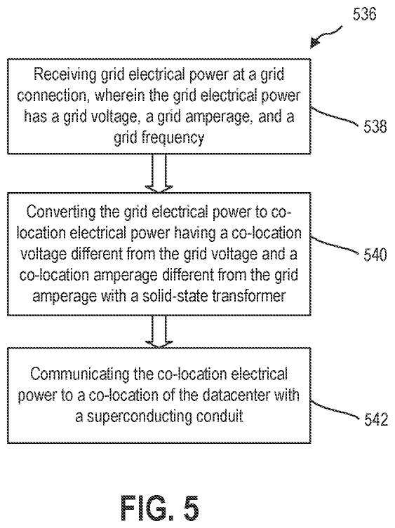

FIG. 5 is a flowchart illustrating a method 536 of datacenter power management, according to at least some embodiments of the present disclosure. In some embodiments, the method 536 includes receiving grid electrical power at a grid connection, where the grid electrical power has a grid voltage, a grid amperage, and a grid frequency at 538.

In some embodiments, the incoming grid electrical power is received with a grid voltage, a grid amperage, and a grid frequency. In some embodiments, the grid voltage is a high voltage no less than 110 kV. In some embodiments, the grid voltage is an extra-high voltage no less than 345 kV. In some embodiments, the grid voltage is an ultra-high voltage no less than 1100 kV.

In some embodiments, the method 536 includes converting the grid electrical power to co-location electrical power having a co-location voltage different from the grid voltage and a co-location amperage different from the grid amperage with at least one solid-state transformer at 540. Stepping down the grid voltage to the co-location voltage of the co-location electrical power produces a high amperage, as the voltage and amperage are inversely proportional for a given power (Wattage), assuming limited or no losses during conversion.

In some embodiments, the co-location electrical power has a co-location voltage that is no more than 240 V. In some embodiments, the co-location electrical power has a co-location voltage that is no more than 120 V. In some embodiments, the co-location electrical power has a co-location voltage that is no more than 48 V. In some embodiments, the co-location electrical power has a co-location voltage that is no more than 12 V. In some embodiments, the co-location electrical power has a co-location voltage that is no more than 5 V.

The greater the step-down in voltage across the solid-state transformer, the greater the increase in amperage. In some embodiments, the co-location amperage is greater than 900 times the grid amperage.

To communicate the co-location electrical power to the co-location(s), in some embodiments, the method 536 further includes communicating the co-location electrical power to a co-location of the datacenter with a superconducting cable at 542. In some embodiments, the superconducting cable is a wire, cable, or other electrical conduit with a resistivity substantially zero. A superconducting cable is a wire, cable, or other electrical conduit that conducts electricity with substantially zero resistance across the length of the electrical conduit when below a critical temperature. In some embodiments, the superconducting cable includes an HTS with a critical temperature no less than 30 K. In some embodiments, the superconducting cable includes an HTS with a critical temperature no less than 77 K. In some embodiments, the superconducting cable includes a low-temperature superconductor with a critical temperature less than 30 K. In some embodiments, the superconducting cable is cooled and/or maintained below the critical temperature with liquid nitrogen cooling, liquid helium cooling, solid-state cooling, or combinations thereof.

In at least some embodiments, the superconducting cable provides electrical communication of the co-location electrical power from the solid-state transformer to the co-location directly with no intervening electrical components. In some embodiments, the superconducting cable provides electrical communication for at least a portion of the electrical connection between the solid-state transformer to the co-location. In some embodiments, the superconducting cable provides electrical communication to a second transformer or other electrical component between the solid-state transformer and the co-location.

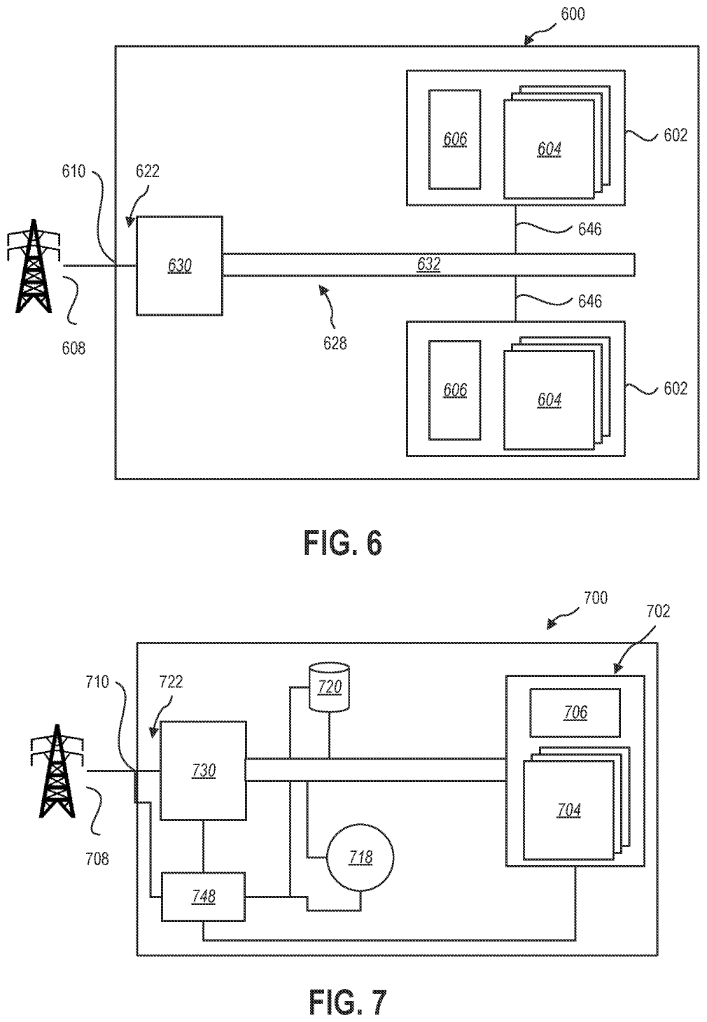

FIG. 6 is a schematic representation of a datacenter power system 600 including co-location branches 646 from a superconducting cable 632, according to at least some embodiments of the present disclosure. In some embodiments, the co-location amperage is distributed across a plurality of co-location branches 646 to a plurality of co-locations 602 in the datacenter. In some embodiments, the datacenter power system 600 receives the grid electrical power 622 from the grid 608 at the grid connection 610, and the solid-state transformer 630 converts the grid electrical power 622 to the co-location electrical power 628. In some embodiments, co-location electrical power 628 is communicated through a superconducting cable 632 as described herein, at least partially due to the high co-location amperage.

The superconducting cable 632 may form a “spine” of the datacenter power system 600 from which a plurality of co-locations 602 draw from the co-location electrical power 628. In some embodiments, the co-location branches 646 are, themselves, superconducting cables. In some embodiments, the co-location branches 646 are non-superconducting cables and include resistive electrical conduits, such as copper wires or cables. While the non-superconducting co-location branches 646 create electrical losses and generate heat, the current from the superconducting cable 632 is distributed across a plurality of co-location branches 646 to reduce the amperage in each of the non-superconducting co-location branches 646. In some embodiments, the non-superconducting co-location branches 646 are shorter than the superconducting cable and/or sufficiently short to thermally manage the heat generated by the non-superconducting co-location branches 646. In some embodiments, a superconducting cable 632 could consist of multiple parallel branches of superconducting cables.

In some embodiments, the plurality of computing devices 604 of the co-location 602 can utilize the co-location electrical power 628 at the co-location voltage. In some embodiments, the co-location 602 includes a PSU 606 that receives and distributes the co-location electrical power 628 to the computing devices 604 of the co-location 602. In some embodiments, the co-location 602 does not have a PSU 606, and the co-location electrical power 628 is delivered to the plurality of computing devices 604 directly and/or without any changes to the co-location voltage and/or co-location frequency.

FIG. 7 is a schematic representation of a datacenter power system including grid participation, according to at least some embodiments of the present disclosure. While embodiments of datacenter power systems described herein include a solid-state transformer to step the voltage down between a grid electrical power and the electrical power used in the datacenter, in some embodiments, the datacenter can export the available power therein back to the grid 708.

In some embodiments, systems and methods described herein include a grid participation controller 748 that communicates with the power grid 708 to reduce electrical energy costs and/or carbon load by selectively receiving or providing electrical power through the grid connection based on grid information including grid pricing information and/or grid source information or grid carbon load information. In some embodiments, the grid participation controller 748 is in data communication with one or more of a generator 718, an energy storage device 720, a co-location 702 (and/or the computing device(s) 704 or PSU 706 thereof), and the solid-state transformer 730 of the datacenter power system 700. In some embodiments, the solid-state transformer 730 can convert electrical power from the power sources and/or energy storage devices of the datacenter power system 700 to a grid voltage and provide electrical power at the grid voltage back to the grid 708.

In some embodiments, the grid participation controller 748 can selectively instruct the additional power sources and/or energy storage devices to selective generate or discharge additional electrical power based at least partially on the grid information. For example, the grid participation controller 748 may instruct the additional power sources and/or energy storage devices to selective generate or discharge additional electrical power based on a carbon load of the grid electrical power 722 available through the grid connection 710.

In some embodiments, the regional power grid 708 receives electricity from a variety of power sources. In some embodiments, the power sources are renewable energy (RE) power sources such as a solar power source and a wind power source that with a lower carbon load but are more intermittent than a combustion power source that generates electricity from carbon fuels, such as a coal. Similarly, grid pricing information may change with day of the week, time of day, and energy source.

In some embodiments, the grid participation controller 748 obtains grid information from the regional power grid 708 to determine the price of electricity from the regional power grid 708 and/or determine a current carbon load of the electricity from the regional power grid 708 based on the energy source(s) supplying to the regional power grid 708. In some examples, the grid participation controller 748 may discharge the additional power source(s) and/or energy storage devices to the co-location(s) 702 during periods of high carbon load and/or high grid pricing from the regional power grid 708. In some examples, the grid participation controller 748 may discharge the additional power sources and/or energy storage devices through the solid-state transformer 730 to provide back to the regional power grid 708 during periods of high carbon load and/or high grid pricing from the regional power grid 708.

Additionally, the intermittent nature of the RE power sources (e.g., solar power source, wind power source) can provide fluctuations in the grid electrical power 722 from the power grid 708. In some embodiments, the grid participation controller 748 obtains grid information from the regional power grid 708 to determine the power supply of the regional power grid 708, and the grid participation controller 748 selectively charges an energy storage device 720 during periods of surplus supply, low carbon load, low grid pricing, and other desirable grid conditions. For example, the grid participation controller 748 may determine a charging plan and discharge plan that discharges the generator 718 and/or energy storage device 720 during periods of low electricity production from RE sources associated with low carbon loads and charges the energy storage device 720 during periods of high electricity production from RE sources associated with low carbon loads.

### INDUSTRIAL APPLICABILITY

The present disclosure generally relates to systems and methods for converting and providing electrical power to a datacenter. In some embodiments, a datacenter power system according to the present disclosure provides more efficient power conversion from a utility grid to a voltage usable for server computers and other computing devices in a datacenter. More particularly, a datacenter power system, in some embodiments, includes a solid-state transformer configured to convert high-voltage grid electrical power to a low-voltage co-location electrical power in a single step, improving efficiency by reducing the electrical losses associated with multiple transformer stages in a conventional system.

In some embodiments, at least a portion of the series of conventional transformers are replaced with a solid-state transformer. In some embodiments, the solid-state transformer converts the high grid voltage of the grid electrical power to a co-location voltage of a co-location electrical power usable by a co-location in a single stage step-down device.

The datacenter power system provides the co-location electrical power to the co-location. In some embodiments, the co-location includes a PSU that receives and distributes the co-location electrical power to the computing devices of the co-location. In some embodiments, the co-location does not have a PSU, and the co-location electrical power is delivered to the plurality of computing devices directly and/or without any changes to the co-location voltage, co-location amperage, co-location frequency, or combinations thereof.

In some embodiments, the co-location includes a plurality of computing devices in one or more server racks. In some embodiments, the co-location includes a plurality of computing devices in one or more server rows containing a plurality of server racks. In some embodiments, the co-location includes a plurality of computing devices in one or more server rooms containing a plurality of server rows. In some embodiments, the datacenter power system distributes the co-location electrical power to a plurality of co-locations.

In some embodiments, the solid-state transformer is an alternating current (AC)-to-AC transformer. In some embodiments, the solid-state transformer can actively regulate voltage and amperage, allowing the solid-state transformer to step-down the grid voltage and also convert a grid frequency of the grid electrical power. In some examples, the solid-state transformer can convert single-phase AC power to three-phase AC power and/or convert three-phase AC power to single-phase AC power. In some embodiments, the solid-state transformer receives an AC input power and outputs a direct current (DC) output power.

The datacenter power system receives high voltage grid electrical power from the utility grid through a grid connection. The incoming grid electrical power is received with a grid voltage, a grid amperage, and a grid frequency. In some embodiments, the grid voltage is a high voltage no less than 110 kV. In some embodiments, the grid voltage is an extra-high voltage no less than 345 kV. In some embodiments, the grid voltage is an ultra-high voltage no less than 1100 kV. Stepping down the grid voltage to the co-location voltage of the co-location electrical power produces a high amperage, as the voltage and amperage are inversely proportional for a given power (Watts), assuming limited or no losses during conversion. With less transformers in the power train, a solid-state transformer allows some embodiments of a datacenter power system to be more efficient, more flexible, and with smaller and lighter power electronic systems.

In some embodiments, the co-location electrical power has a co-location voltage that is no more than 240 Volts (V). In some embodiments, the co-location electrical power has a co-location voltage that is no more than 120 V. In some embodiments, the co-location electrical power has a co-location voltage that is no more than 48 V. In some embodiments, the co-location electrical power has a co-location voltage that is no more than 12 V. In some embodiments, the co-location electrical power has a co-location voltage that is no more than 5 V.

The greater the step-down in voltage across the solid-state transformer, the greater the increase in amperage. In some embodiments, the co-location amperage is greater than 900 times the grid amperage. To communicate the co-location electrical power to the co-location(s), in some embodiments, a datacenter power system includes a superconducting cable. In some embodiments, the superconducting cable is a wire, cable, or other electrical conduit with a resistivity substantially zero. A superconducting cable is a wire, cable, or other electrical conduit that conducts electricity with substantially zero resistance across the length of the electrical conduit when below a critical temperature. In some embodiments, the superconducting cable includes a high-temperature superconductor (HTS) with a critical temperature no less than 30 Kelvin (K). In some embodiments, the superconducting cable includes an HTS with a critical temperature no less than 77 K. In some embodiments, the superconducting cable includes a low-temperature superconductor with a critical temperature less than 30 K. In some embodiments, the superconducting cable is cooled and/or maintained below the critical temperature with liquid nitrogen cooling, liquid helium cooling, solid-state cooling, or combinations thereof.

In at least some embodiments, the superconducting cable provides electrical communication of the co-location electrical power from the solid-state transformer to the co-location directly with no intervening electrical components. In some embodiments, the superconducting cable provides electrical communication for at least a portion of the electrical connection between the solid-state transformer to the co-location. For example, and as will be described in more detail herein, the superconducting cable may provide electrical communication to a second transformer or other electrical component between the solid-state transformer and the co-location.

In some embodiments, at least a portion of the superconducting cable communicates electrical power (e.g., co-location electrical power) having an amperage (e.g., co-location amperage) greater than 90,000 Amperes (A). In some embodiments, the entire superconducting cable communicates electrical power having an amperage greater than 90,000 A. For example, a grid electrical power with a 110 kV grid voltage and 100 A grid amperage may be converted to a co-location electrical power with a 120 V co-location voltage and an approximate 91,700 A co-location amperage. In some embodiments, at least a portion of the superconducting cable communicates electrical power (e.g., co-location electrical power) having an amperage (e.g., co-location amperage) greater than 200,000 A. For example, a grid electrical power with a 110 kV grid voltage and 100 A grid amperage may be converted to a co-location electrical power with a 48 V co-location voltage and an approximate 229,000 A co-location amperage. In some embodiments, at least a portion of the superconducting cable communicates electrical power (e.g., co-location electrical power) having an amperage (e.g., co-location amperage) greater than 2,000,000 A. For example, a grid electrical power with a 110 kV grid voltage and 100 A grid amperage may be converted to a co-location electrical power with a 48 V co-location voltage and an approximate 2,200,000 A co-location amperage.

A superconducting cable conveys the electrical power with substantially no resistance, allowing high amperages without the associated electrical loss and heat generation of resistive conduits, such as copper wire or cable. In some embodiments, the superconducting cable includes or is made of a first-generation or second-generation superconductor. First-generation superconductors include, in some examples, bismuth strontium calcium copper oxide materials. In some examples, second-generation superconductors include rare-earth barium copper oxide materials.

In some embodiments, the datacenter power system includes additional power sources or storage devices, such as a generator and/or battery storage devices electrically between the solid-state transformer and the co-location (e.g., at the superconducting cable). In some examples, the additional power sources or storage devices, such as the generator and/or battery storage devices, are coupled to the datacenter power system at different stages of the voltage depending on the provided voltage of the additional power sources or storage devices.

In some embodiments, the grid provides different amounts of grid electrical power to the grid connection depending on time of day, day of the week, time of the year, weather, local grid infrastructure, etc. In some embodiments, a datacenter power system includes additional power sources or storage devices to supplement the electrical power in the datacenter, such as the available co-location electrical power. In some embodiments, a generator (e.g., solar generator, thermal generator, combustion generator) provides additional electrical power to the co-location electrical power to supplement the co-location electrical power when the grid electrical power is less than required by the co-locations of the datacenter. In some embodiments, a storage device (such as a battery) can receive and store surplus electrical power when available. In some embodiments, a storage device (such as a battery, hydrogen fuel cell, metal fuel cell) can provide additional electrical power to the co-location electrical power when the grid electrical power is less than required by the co-locations of the datacenter.

In some embodiments, the additional power sources or storage devices provide the additional electrical power to the co-location electrical power at the co-location voltage and co-location frequency for use at the co-location (either directly by the computing devices or via a PSU). In some embodiments, the power sources or storage devices provide additional electrical power at different voltage and frequency than the co-location electrical power. In such embodiments, the additional power sources or storage devices may provide the additional electrical power to the power train between a solid-state transformers.

In some embodiments, additional power sources or storage devices provide additional electrical power at the middle-voltage electrical power or low-voltage electrical power. For example, the generator and/or energy storage device(s) may provide power to an uninterruptable power supply (UPS) electrically between a first solid-state transformer and a second solid-state transformer. A component, device, conduit, or location of the datacenter power system is electrically between a first component and a second component when the electrical power passes through that component, device, conduit, or location during transmission from the first component to the second component. For example, the first superconducting cable may be electrically between the first solid-state transformer and the second solid-state transformer, and the second superconducting cable may be electrically between the second solid-state transformer and the co-location.

In some embodiments, the first solid-state transformer converts the grid electrical power received from the grid at the grid connection to a lower voltage and higher amperage electrical power, such as the low-voltage electrical power. In some embodiments, additional power sources and/or storage devices provide additional power at the low voltage of the low-voltage electrical power to supplement the available power that is provided to the second solid-state transformer. The second solid-state transformer subsequently steps the voltage of the low-voltage electrical power down to the co-location voltage of the co-location electrical power in the second superconducting cable.

In some embodiments, the plurality of computing devices of the co-location can utilize the co-location electrical power at the co-location voltage. In some embodiments, the co-location includes a PSU that receives and distributes the co-location electrical power to the computing devices of the co-location. In some embodiments, the co-location does not have a PSU, and the co-location electrical power is delivered to the plurality of computing devices directly and/or without any changes to the co-location voltage, co-location amperage, co-location frequency, or combinations thereof.

In some embodiments, a DC UPS is electrically between the first solid-state transformer and the first superconducting cable (and/or between the second solid-state transformer and the second superconducting cable). The DC UPS receives electrical power from the first solid-state transformer and discharges to the first superconducting cable to provide an uninterrupted electrical power in the event of a change to or loss of the grid electrical power.

In some embodiments, a generator provides additional electrical power electrically between the first solid-state transformer and the first superconducting cable (and/or between the second solid-state transformer and the second superconducting cable). In some embodiments, the generator provides the additional electrical power at the output voltage and frequency of the adjacent solid-state transformer in the event of a change to or loss of the grid electrical power.

In some embodiments, a generator UPS (gUPS) is between the first solid-state transformer and the first superconducting cable (and/or between the second solid-state transformer and the second superconducting cable). In some embodiments, the gUPS allows a generator to provide an uninterrupted electrical power in the event of a change to or loss of the grid electrical power at the output voltage and frequency of the adjacent solid-state transformer.

In some embodiments, the method of datacenter power management includes receiving grid electrical power at a grid connection, where the grid electrical power has a grid voltage, a grid amperage, and a grid frequency.

In some embodiments, the incoming grid electrical power is received with a grid voltage, a grid amperage, and a grid frequency. In some embodiments, the grid voltage is a high voltage no less than 110 kV. In some embodiments, the grid voltage is an extra-high voltage no less than 345 kV. In some embodiments, the grid voltage is an ultra-high voltage no less than 1100 kV.

In some embodiments, the method includes converting the grid electrical power to co-location electrical power having a co-location voltage different from the grid voltage and a co-location amperage different from the grid amperage with at least one solid-state transformer. Stepping down the grid voltage to the co-location voltage of the co-location electrical power produces a high amperage, as the voltage and amperage are inversely proportional for a given power (Wattage), assuming limited or no losses during conversion.

In some embodiments, the co-location electrical power has a co-location voltage that is no more than 240 V. In some embodiments, the co-location electrical power has a co-location voltage that is no more than 120 V. In some embodiments, the co-location electrical power has a co-location voltage that is no more than 48 V. In some embodiments, the co-location electrical power has a co-location voltage that is no more than 12 V. In some embodiments, the co-location electrical power has a co-location voltage that is no more than 5 V.

The greater the step-down in voltage across the solid-state transformer, the greater the increase in amperage. In some embodiments, the co-location amperage is greater than 900 times the grid amperage.

To communicate the co-location electrical power to the co-location(s), in some embodiments, the method further includes communicating the co-location electrical power to a co-location of the datacenter with a superconducting cable. In some embodiments, the superconducting cable is a wire, cable, or other electrical conduit with a resistivity substantially zero. A superconducting cable is a wire, cable, or other electrical conduit that conducts electricity with substantially zero resistance across the length of the electrical conduit when below a critical temperature. In some embodiments, the superconducting cable includes an HTS with a critical temperature no less than 30 K. In some embodiments, the superconducting cable includes an HTS with a critical temperature no less than 77 K. In some embodiments, the superconducting cable includes a low-temperature superconductor with a critical temperature less than 30 K. In some embodiments, the superconducting cable is cooled and/or maintained below the critical temperature with liquid nitrogen cooling, liquid helium cooling, solid-state cooling, or combinations thereof.

In at least some embodiments, the superconducting cable provides electrical communication of the co-location electrical power from the solid-state transformer to the co-location directly with no intervening electrical components. In some embodiments, the superconducting cable provides electrical communication for at least a portion of the electrical connection between the solid-state transformer to the co-location. In some embodiments, the superconducting cable provides electrical communication to a second transformer or other electrical component between the solid-state transformer and the co-location.

In some embodiments, the co-location amperage is distributed across a plurality of co-location branches to a plurality of co-locations in the datacenter. In some embodiments, the datacenter power system receives the grid electrical power from the grid at the grid connection, and the solid-state transformer converts the grid electrical power to the co-location electrical power. In some embodiments, co-location electrical power is communicated through a superconducting cable as described herein, at least partially due to the high co-location amperage.

The superconducting cable may form a “spine” of the datacenter power system from which a plurality of co-locations draw from the co-location electrical power. In some embodiments, the co-location branches are, themselves, superconducting cables. In some embodiments, the co-location branches are non-superconducting cables and include resistive electrical conduits, such as copper wires or cables. While the non-superconducting co-location branches create electrical losses and generate heat, the current from the superconducting cable is distributed across a plurality of co-location branches to reduce the amperage in each of the non-superconducting co-location branches. In some embodiments, the non-superconducting co-location branches are shorter than the superconducting cable and/or sufficiently short to thermally manage the heat generated by the non-superconducting co-location branches.

In some embodiments, the plurality of computing devices of the co-location can utilize the co-location electrical power at the co-location voltage. In some embodiments, the co-location includes a PSU that receives and distributes the co-location electrical power to the computing devices of the co-location. In some embodiments, the co-location does not have a PSU, and the co-location electrical power is delivered to the plurality of computing devices directly and/or without any changes to the co-location voltage and/or co-location frequency.

In some embodiments, a datacenter power system includes grid participation. While embodiments of datacenter power systems described herein include a solid-state transformer to step the voltage down between a grid electrical power and the electrical power used in the datacenter, in some embodiments, the datacenter can export the available power therein back to the grid.

In some embodiments, systems and methods described herein include a grid participation controller that communicates with the power grid to reduce electrical energy costs and/or carbon load by selectively receiving or providing electrical power through the grid connection based on grid information including grid pricing information and/or grid source information or grid carbon load information. In some embodiments, the grid participation controller is in data communication with one or more of a generator, an energy storage device, a co-location (and/or the computing device(s) or PSU thereof), and the solid-state transformer of the datacenter power system. In some embodiments, the solid-state transformer can convert electrical power from the power sources and/or energy storage devices of the datacenter power system to a grid voltage and provide electrical power at the grid voltage back to the grid.

In some embodiments, the grid participation controller can selectively instruct the additional power sources and/or energy storage devices to selective generate or discharge additional electrical power based at least partially on the grid information. For example, the grid participation controller may instruct the additional power sources and/or energy storage devices to selective generate or discharge additional electrical power based on a carbon load of the grid electrical power available through the grid connection.

In some embodiments, the regional power grid receives electricity from a variety of power sources. In some embodiments, the power sources are renewable energy (RE) power sources such as a solar power source and a wind power source that with a lower carbon load but are more intermittent than a combustion power source that generates electricity from carbon fuels, such as a coal. Similarly, grid pricing information may change with day of the week, time of day, and energy source.

In some embodiments, the grid participation controller obtains grid information from the regional power grid to determine the price of electricity from the regional power grid and/or determine a current carbon load of the electricity from the regional power grid based on the energy source(s) supplying to the regional power grid. In some examples, the grid participation controller may discharge the additional power source(s) and/or energy storage devices to the co-location(s) during periods of high carbon load and/or high grid pricing from the regional power grid. In some examples, the grid participation controller may discharge the additional power sources and/or energy storage devices through the solid-state transformer to provide back to the regional power grid during periods of high carbon load and/or high grid pricing from the regional power grid.

Additionally, the intermittent nature of the RE power sources (e.g., solar power source, wind power source) can provide fluctuations in the grid electrical power from the power grid. In some embodiments, the grid participation controller obtains grid information from the regional power grid to determine the power supply of the regional power grid, and the grid participation controller selectively charges an energy storage device during periods of surplus supply, low carbon load, low grid pricing, and other desirable grid conditions. For example, the grid participation controller may determine a charging plan and discharge plan that discharges the generator and/or energy storage device during periods of low electricity production from RE sources associated with low carbon loads and charges the energy storage device during periods of high electricity production from RE sources associated with low carbon loads.

The present disclosure relates to systems and methods for providing and converting electrical power in a datacenter according to at least the examples provided in the clauses below:

Clause 1. A datacenter power system comprising: a grid connection configured to receive grid electrical power at a grid voltage, a grid amperage, and a grid frequency; a co-location including a plurality of computing devices; a solid-state transformer in electrical communication with the grid connection and configured to convert the grid electrical power to co-location electrical power having a co-location voltage different from the grid voltage and a co-location amperage different from the grid amperage; and a superconducting cable providing electrical communication of the co-location electrical power from the solid-state transformer to the co-location.

Clause 2. The datacenter power system of clause 1, wherein the co-location electrical power has a co-location frequency different from the grid frequency.

Clause 3. The datacenter power system of clause 1, wherein the superconducting cable includes a high-temperature superconductor.

Clause 4. The datacenter power system of clause 1 or 2, wherein the co-location voltage is no more than 120 Volts.

Clause 5. The datacenter power system of any preceding clause, wherein the co-location voltage is no more than 48 Volts.

Clause 6. The datacenter power system of any preceding clause, wherein the co-location amperage in at least a portion of the superconducting cable is at least 90,000 A.

Clause 7. The datacenter power system of any preceding clause, wherein the co-location amperage in at least a portion of the superconducting cable is at least 200,000 A.

Clause 8. The datacenter power system of any preceding clause, wherein the superconducting cable electrically connects the solid-state transformer directly to the co-location.

Clause 9. The datacenter power system of any preceding clause further comprising a generator uninterruptable power supply electrically between the solid-state transformer and the superconducting cable.

Clause 10. The datacenter power system of any preceding clause further comprising a generator electrically between the solid-state transformer and the superconducting cable.

Clause 11. The datacenter power system of any preceding clause further comprising a direct current uninterruptable power supply electrically between the solid-state transformer and the superconducting cable.

Clause 12. The datacenter power system of any preceding clause further comprising a second co-location and the superconducting cable provides electrical communication of the co-location electrical power with the co-location voltage to the second co-location.

Clause 13. The datacenter power system of any preceding clause wherein the solid-state transformer is a first solid-state transformer of a plurality of solid-state transformers.

Clause 14. A method of power management in a datacenter, the method comprising: receiving grid electrical power at a grid connection, wherein the grid electrical power has a grid voltage, a grid amperage, and a grid frequency; converting the grid electrical power to co-location electrical power having a co-location voltage different from the grid voltage and a co-location amperage different from the grid amperage with a solid-state transformer; and communicating the co-location electrical power to a co-location of the datacenter with a superconducting cable.

Clause 15. The method of clause 14, wherein the grid voltage is at least high voltage, and the co-location voltage is no more than 120 Volts, and the solid-state transformer converts the high voltage to no more than 120 Volts directly.

Clause 16. The method of clause 14, wherein the grid voltage is at least high voltage, and the co-location voltage is no more than 120 Volts, and converting the grid electrical power to co-location electrical power includes converting the grid voltage to a middle voltage with a first solid-state transformer and converting the middle voltage to the co-location voltage with at least a second solid-state transformer.

Clause 17. The method of any of clauses 14-16, wherein converting the grid electrical power to co-location electrical power includes converting the grid frequency to a co-location frequency different from the grid frequency with the solid-state transformer.

Clause 18. The method of any of clauses 14-17, further comprising powering at least one computing device of the co-location at the co-location voltage.

Clause 19. A datacenter power system comprising: a grid connection configured to receive grid electrical power at a grid voltage, a grid amperage, and a grid frequency; a plurality of co-locations, each co-location including a plurality of computing devices; a solid-state transformer in electrical communication with the grid connection and configured to convert the grid electrical power to co-location electrical power having a co-location voltage different from the grid voltage and a co-location amperage different from the grid amperage; a superconducting cable providing electrical communication of the co-location electrical power from the solid-state transformer to the co-location; and a plurality of branch conduits from the superconducting cable that provide electrical communication to the plurality of co-locations.

Clause 20. The datacenter power system of clause 19, wherein at least one branch conduit of the plurality of branch conduits is a high temperature superconductor.

Clause 21. A method of managing power in a datacenter, the method comprising: obtaining grid information from a regional power grid; obtaining a state information of a power source or energy storage device of the datacenter power system; determining a discharge schedule of the power source or energy storage device based at least partially on the grid information and the co-location power demands; converting at least a portion of electrical power from the power source or energy storage device to a grid voltage with a solid-state transformer; and providing the converted electrical power to the regional power grid.

Clause 22. The method of clause 21, further comprising determining a charging schedule of the power source or energy storage device of the datacenter power system for the datacenter based at least partially on the grid information and the datacenter power demands.

Clause 23. The method of clauses 21 or 22, wherein the grid information includes grid sources, and the discharge schedule is based at least partially on the grid sources.

Clause 24. The method of any of clauses 21 through 23, wherein the grid information includes carbon load, and the discharge schedule is based at least partially on the carbon load.

The articles “a,” “an,” and “the” are intended to mean that there are one or more of the elements in the preceding descriptions. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. For example, any element described in relation to an embodiment herein may be combinable with any element of any other embodiment described herein. Numbers, percentages, ratios, or other values stated herein are intended to include that value, and also other values that are “about” or “approximately” the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the scope of the present disclosure, and that various changes, substitutions, and alterations may be made to embodiments disclosed herein without departing from the scope of the present disclosure. Equivalent constructions, including functional “means-plus-function” sections are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the embodiments that falls within the meaning and scope of the claims is to be embraced by the claims.
It should be understood that any directions or reference frames in the preceding description are merely relative directions or movements. For example, any references to “front” and “back” or “top” and “bottom” or “left” and “right” are merely descriptive of the relative position or movement of the related elements.
The present disclosure may be embodied in other specific forms without departing from its characteristics. The described embodiments are to be considered as illustrative and not restrictive. The scope of the disclosure is, therefore, indicated by the appended claims rather than by the foregoing description. Changes that come within the meaning and range of equivalency of the claims are to be embraced within their scope.

What is claimed is:

1. A datacenter power system comprising:
a grid connection configured to receive grid electrical power at a grid voltage, a grid amperage, and a grid frequency;
a co-location including a plurality of computing devices;
a solid-state transformer in electrical communication with the grid connection and configured to convert the grid electrical power to co-location electrical power having a co-location voltage different from the grid voltage and a co-location amperage different from the grid amperage; and
a superconducting cable providing electrical communication of the co-location electrical power from the solid-state transformer to the co-location.

2. The datacenter power system of claim 1, wherein the co-location electrical power has a co-location frequency different from the grid frequency.

3. The datacenter power system of claim 1, wherein the superconducting cable includes a high-temperature superconductor.

4. The datacenter power system of claim 1, wherein the co-location voltage is no more than 120 Volts.

5. The datacenter power system of claim 1, wherein the co-location voltage is no more than 48 Volts.

6. The datacenter power system of claim 1, wherein the co-location amperage in at least a portion of the superconducting cable is at least 90,000 A.

7. The datacenter power system of claim 1, wherein the co-location amperage in at least a portion of the superconducting cable is at least 200,000 A.

8. The datacenter power system of claim 1, wherein the superconducting cable electrically connects the solid-state transformer directly to the co-location.

9. The datacenter power system of claim 1 further comprising a generator uninterruptable power supply electrically between the solid-state transformer and the superconducting cable.

10. The datacenter power system of claim 1 further comprising a generator electrically between the solid-state transformer and the superconducting cable.

11. The datacenter power system of claim 1 further comprising a direct current uninterruptable power supply electrically between the solid-state transformer and the superconducting cable.

12. The datacenter power system of claim 1 further comprising a second co-location and the superconducting cable provides electrical communication of the co-location electrical power with the co-location voltage to the second co-location.

13. The datacenter power system of claim 1 wherein the solid-state transformer is a first solid-state transformer of a plurality of solid-state transformers.

14. A method of power management in a datacenter, the method comprising:
receiving grid electrical power at a grid connection, wherein the grid electrical power has a grid voltage, a grid amperage, and a grid frequency;
converting the grid electrical power to co-location electrical power having a co-location voltage different from the grid voltage and a co-location amperage different from the grid amperage with a solid-state transformer; and
communicating the co-location electrical power to a co-location of the datacenter with a superconducting cable.

15. The method of claim 14, wherein the grid voltage is at least high voltage, and the co-location voltage is no more than 120 Volts, and the solid-state transformer converts the high voltage to no more than 120 Volts directly.

16. The method of claim 14, wherein the grid voltage is at least high voltage, and the co-location voltage is no more than 120 Volts, and converting the grid electrical power to co-location electrical power includes converting the grid voltage to a middle voltage with a first solid-state transformer and converting the middle voltage to the co-location voltage with at least a second solid-state transformer.

17. The method of claim 14, wherein converting the grid electrical power to co-location electrical power includes converting the grid frequency to a co-location frequency different from the grid frequency with the solid-state transformer.

18. The method of claim 14, further comprising powering at least one computing device of the co-location at the co-location voltage.

19. A datacenter power system comprising:
a grid connection configured to receive grid electrical power at a grid voltage, a grid amperage, and a grid frequency;
a plurality of co-locations, each co-location including a plurality of computing devices;
a solid-state transformer in electrical communication with the grid connection and configured to convert the grid electrical power to co-location electrical power having a co-location voltage different from the grid voltage and a co-location amperage different from the grid amperage;
a superconducting cable providing electrical communication of the co-location electrical power from the solid-state transformer to the co-location; and
a plurality of branch conduits from the superconducting cable that provide electrical communication to the plurality of co-locations.

20. The datacenter power system of claim 19, wherein at least one branch conduit of the plurality of branch conduits is a high temperature superconductor.
